(19) United States
(12) Patent Application Publication
(10) Pub. No.: US 2025/0206600 A1
(43) Pub. Date: Jun. 26, 2025

(54) ACOUSTIC SENSOR DEVICES WITH MULTIPLE SENSING ELEMENTS

(71) Applicant: Soundskrit Inc., Montreal (CA)

(72) Inventors: Wan-Thai Hsu, Saline, MI (US); Sahil Gupta, Montreal (CA); Stephane Leahy, Montreal (CA)

(21) Appl. No.: 18/847,109

(22) PCT Filed: Mar. 16, 2023
(86) PCT No.: PCT/US2023/015343

§ 371 Date: Sep. 13, 2024

Related U.S. Application Data
(60) Provisional application No. 63/320,467, filed on Mar. 16, 2022.

(51) Int. Cl. B81B 7/00; H04R 1/40

(52) U.S. Cl. CPC B81B 7/0061; H04R 1/406; B81B 2201/0257; B81B 2203/0127; B81B 2203/0136; B81B 2203/0307; B81B 2203/0315; B81B 2207/012; H04R 2201/003

(57) ABSTRACT

An acoustic sensor device comprises a package, a substrate disposed in the package or forming a part of the package, and one or more microelectromechanical system (MEMS) transducers supported by the substrate and packaged in the package. The one or more MEMS transducers include a plurality of sensing elements including at least a first sensing element and a second sensing element. The one or more MEMS transducers are positioned in the package such the first sensing element exhibits a first directionality pick-up pattern with respect to sound waves traveling in an ambient environment of the acoustic sensor device and the second sensing element exhibits a second directionality pick-up pattern with respect to the sound waves traveling in the ambient environment of the acoustic sensor device. The second directionality pick-up pattern is different from the first directionality pick-up pattern.

### CROSS-REFERENCES TO RELATED APPLICATIONS

This application claims the benefit of U.S. provisional application entitled “Multi-Transducer Microphone,” filed Mar. 16, 2022, and assigned Ser. No. 63/320,467, the entire disclosure of which is hereby expressly incorporated by reference.

### BACKGROUND OF THE DISCLOSURE

### Field of the Disclosure

The disclosure relates generally to microelectromechanical system (MEMS) microphones.

### Brief Description of Related Technology

Traditional omnidirectional acoustic sensors (e.g., microphones) measure the pressure of incoming sound. A transducer, or membrane, that moves in response to the incoming sound is encapsulated in a package. The transducer partitions the package into two air volumes, a front air volume and a back air volume. The microphone package has a sound port that couples one of the air volumes to the outside ambient environment (e.g., ambient air). As sound hits the microphone, the sound couples into one of the air volumes through the sound port and changes the pressure. This creates a difference in pressure between the front air volume and the back air volume that creates a force on the transducer and drives its motion. In this configuration, the omnidirectional microphone responds equally to sound travelling at all directions.

Directional acoustic sensors, on the other hand, use two sound ports, exposing each opposing side of the transducer to the ambient environment. They are designed to have high sensitivity to sound travelling in one direction and low sensitivity to sound travelling in another direction. Directionality allows the acoustic sensor to separate sound sources.

For example, a dipole acoustic sensor is typically designed to have relatively higher sensitivity to sound emanating from the front and the back of the acoustic sensor and relatively lower sensitivity to sound emanating from the sides of the acoustic sensor. Thus, although dipole acoustic sensors provide directionality, dipole acoustic sensors typically pick up sounds from both the front and the back of the acoustic sensor. In certain scenarios, it may be useful to reject sound originating behind the acoustic sensor device using a different pickup pattern such as a cardioid. By adding an acoustic delay element in the back of a dipole acoustic sensor device package, the pattern of the acoustic sensor device can be converted into a cardioid. However, such packaging techniques to achieve a cardioid pattern often result in the acoustic sensors being frequency dependent. Thus, the directionality pattern of the cardioid acoustic sensor device typically changes as a function of frequency.

### SUMMARY OF THE DISCLOSURE

In accordance with one aspect of the disclosure, an acoustic sensor device comprises a package, a substrate disposed in the package or forming a part of the package, and one or more microelectromechanical system (MEMS) transducers supported by the substrate and packaged in the package. The one or more MEMS transducers include a plurality of sensing elements including at least a first sensing element and a second sensing element. The one or more MEMS transducers are positioned in the package such the first sensing element exhibits a first directionality pick-up pattern with respect to sound waves traveling in an ambient environment of the acoustic sensor device and the second sensing element exhibits a second directionality pick-up pattern with respect to the sound waves traveling in the ambient environment of the acoustic sensor device, wherein the second directionality pick-up pattern is different from the first directionality pick-up pattern.

In accordance with another aspect of the disclosure, an acoustic sensor device comprises a package, a substrate disposed in the package or forming a part of the package, and one or more microelectromechanical system (MEMS) transducers supported by the substrate and packaged in the package, the one or more MEMS transducers including a plurality of sensing elements including at least a first sensing element and a second sensing element. The acoustic sensor device further comprises a first sound port formed in the package and configured to expose a first side of the first sensing element and a first side of the second sensing element to an ambient environment, and a second sound port formed in the package and configured to couple a second side of the first sensing element to the ambient environment such that the first sensing element exhibits a directional pick-up pattern with respect to sound waves traveling in the ambient environment. A second side of the second sensing element is not exposed to the ambient environment such that the second sensing element exhibits an omnidirectional pick-up pattern with respect to the sound waves traveling in the ambient environment.

In connection with any one of the aforementioned aspects, the acoustic sensor devices may alternatively or additionally include or involve any combination of one or more of the following aspects or features. The one or more MEMS transducers are placed in the package such that the first sensing element exhibits a dipole directional pick-up pattern, and the second sensing element exhibits an omnidirectional pick-up pattern. The acoustic sensor device further comprises a first air volume formed in the package on a first side of the first sensing element, a first sound port formed in the package of the acoustic sensor device, the first sound port configured to expose the first side of the first sensing element to the ambient environment via the first air volume, a second air volume formed in the package on a second side of the first sensing element, the second side being of the first sensing element being opposite the first side of the first sensing element, and a second sound port formed in the package, the second sound port configured to expose the second side of the first sensing element to the ambient environment via the second air volume. The first sound port is configured to further expose a first side of the second sensing element to the ambient environment via the first air volume. The acoustic sensor device further comprises a sealed air volume formed at least partially in the package of the acoustic sensor device on a second side of the second sensing element, the second side of the second sensing element being opposite the first side of the second sensing element. The second sensing element is formed on a semiconductor die, and the sealed air volume comprises a cavity in the semiconductor die underneath the second sensing element. The semiconductor die is placed on the substrate of the acoustic sensor device, and the substrate of the acoustic sensor device includes an opening formed therein underneath the cavity in the semiconductor die such that the sealed air volume extends into the opening in the substrate of the acoustic sensor device. The sealed air volume is configured to further extend into a cavity formed in a substrate of an end product device into which the acoustic sensor device is integrated. The sealed air volume further is configured to further extend into a sealed air volume formed in a package of the end product device into which the acoustic sensor device is integrated. The one or more MEMS transducers include a first MEMS transducer including the first sensing element and a second MEMS transducer including the second sensing element, wherein the first MEMS transducer is formed in a first semiconductor die and the second MEMS transducer is formed in a second semiconductor die separate from the first semiconductor die. The one or more MEMS transducers include a single MEMS transducer formed on a semiconductor die, the single MEMS transducer including i) the first sensing element, ii) a first cavity formed in the semiconductor die underneath the first sensing element, iii) the second sensing element, and iv) a second cavity formed in the semiconductor die underneath the second sensing element, the second cavity being separated from the first cavity in the semiconductor die. The acoustic sensor device further comprises one or more integrated circuit (IC) devices disposed in the package and electrically coupled to the one or more MEMS transducers, the one or more IC devices configured to read out and process a first electrical signal generated based on movement of the first sensing element and a second electrical signal generated based on movement of the second sensing element, the first electrical signal corresponding to the first directionality pick-up pattern exhibited by the first sensing element and the second electrical signal corresponding to the second directionality pick-up pattern exhibited by the second sensing element. The one or more MEMS transducers include a first MEMS transducer including the first sensing element and a second MEMS transducer including the second sensing element. The one or more IC devices include a first application specific integrated circuit (ASIC) electrically coupled to the first MEMS transducer, the first ASIC configured to read out and process the first electrical signal generated based on the movement of the first sensing element of the first MEMS transducer, and a second ASIC electrically coupled to the second MEMS transducer, the second ASIC configured to read out and process the second electrical signal generated based on the movement of the second sensing element of the second MEMS transducer. The one or more IC devices include an application specific integrated circuit (ASIC) configured to read out and process both the first electrical signal generated based on the movement of the first sensing element and the second electrical signal generated based on the movement of the second sensing element. The ASIC is configured to selectively generate one or more of i) a first sensor output signal based on the first electrical signal generated based on the movement of the first sensing element, the first sensor output signal corresponding to the first directionality pick-up pattern exhibited by the first sensing element ii) a second sensor output signal based on the second electrical signal generated based on the movement of the second sensing element, the second sensor output signal corresponding to the second directionality pick-up pattern exhibited by the second sensing element, and iii) a third sensor output signal based on a combination of the first electrical signal generated based on the movement of the first sensing element and the second electrical signal generated based on the movement of the second sensing element, the third sensor output signal corresponding to a third directionality pick-up pattern that is different from the first directionality pick-up pattern exhibited by the first sensing element and the second directionality pick-up pattern of exhibited by the second sensing element. The first directionality pick-up pattern comprises a dipole directional pattern, the second directionality pick-up pattern comprises an omnidirectional pattern, and the third directionality pick-up pattern comprises one of a cardioid pattern, a super-cardioid pattern, and a hyper-cardioid pattern. The ASIC is configured to generate a sound intensity output based on a multiplication the first electrical signal generated based on the movement of the first sensing element with the second electrical signal generated based on the movement of the second sensing element. The acoustic sensor device further comprises a first air volume, a second air volume and a third air volume. The first side of the first sensing element and the first side of the second sensing element are both exposed to the first air volume such that the first sound port exposes the first side to the first sensing element and the first side of the second sensing element to the ambient environment via the first air volume. The second side of the first sensing element is exposed to the second air volume such that the second sound port exposes the second side of the first sensing element to the ambient environment via the second air volume. The second side of the second sensing element is exposed to the third air volume. The third air volume is sealed from the ambient environment. The acoustic sensor device further comprises at least one IC device coupled to the one or more MEMS transducers, the at least one IC device configured to selectively generate one or more of i) a directional sensor output signal generated based on movement of the first sensing element ii) an omnidirectional sensor output signal generated based on movement of the second sensing element, and ii) a combined sensor output signal generated based on a combination of the directional sensor output signal and the omnidirectional sensor output signal. The first sensing element is formed on a first semiconductor die, and the second sensing element is formed on a second semiconductor dies separate from the first semiconductor die. The first sensing element and the second sensing element are formed a semiconductor die, wherein the semiconductor die comprises the first sensing element positioned over a first cavity formed in the semiconductor die and the second sensing element positioned over a second cavity formed in the semiconductor die, the second cavity being separate from the first cavity in the semiconductor die.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a block diagram of an example sensing environment in which an acoustic sensor device having multiple sensing elements that exhibit different directionality patterns may be utilized, in accordance with an example.

FIG. 2 is a cross-sectional, schematic view of an example acoustic sensor device having multiple sensing elements that exhibit different directionality patterns, in accordance with an example.

FIG. 3 is a cross-sectional, schematic view of another example acoustic sensor device having multiple sensing elements that exhibit different directionality patterns, in accordance with another example.

FIG. 4 is a cross-sectional, schematic view of example acoustic sensor having multiple sensing elements and an enlarged sealed air volume, in accordance with an example.

FIG. 5 is a cross-sectional, schematic view of another example acoustic sensor device having multiple sensing elements and an enlarged sealed air volume, in accordance with another example.

FIG. 6 is a cross-sectional, schematic view of example another acoustic sensor device having multiple sensing elements and an enlarged sealed air volume, in accordance with yet another example.

FIG. 7 is a cross-sectional, schematic view of another example acoustic sensor device having multiple sensing elements and an enlarged sealed air volume, in accordance with still another example.

FIG. 8 is a top, schematic view of an example transducer having a sensing element formed in a semiconductor die, in accordance with an example.

FIG. 9 is a top, schematic view of an example transducer having multiple sensing elements formed in a semiconductor die, in accordance with an example.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Acoustic sensor devices, such as microphones, that are equipped with multiple sensing elements, such as multiple diaphragms, packaged in a same package are described. In an aspect, the multiple sensing elements are positioned in the package of the acoustic sensor device such that respective ones of the sensing elements have different pick-up patterns with respect to direction of travel of sound waves in an ambient environment around the acoustic sensor device. The acoustic sensor device may thus produce multiple sensor outputs having different directionality patterns corresponding to the pick-up patterns of the sensing elements of the acoustic sensor device. For example, two sensing elements may be packaged in a package of an acoustic sensor device such that two opposing sides of a first sensing element are exposed to an ambient environment, while only one side of a second sensing element is exposed to the ambient environment. In this configuration, the first sensing element may exhibit a dipole directional pick-up pattern, or a pick-up pattern having at least substantially dipole shape, with respect to sound waves traveling in the ambient environment and the second sensing element exhibits an omnidirectional, or at least substantially omnidirectional, pick-up pattern with respect to the sound waves traveling in the ambient environment. Thus, a directional output and an omnidirectional output may be provided by the single acoustic sensor device. Although the directional sensor output is generally described herein as being a dipole directional sensor output, it is noted that the directional sensor output may be a distorted dipole output or a directional sensor output having directionality other than a dipole, in some examples.

In an aspect, the different sensor outputs produced by the acoustic sensor device may be selectively utilized based on an environment of the acoustic sensor device or a purpose of use of the acoustic sensor device. For example, an omnidirectional sensor output of the acoustic sensor device may be used in situations in which omnidirectional capture of sound is desired. On the other hand, the dipole directional sensor output of the acoustic sensor device may be selected when rejection of sound from some directions, such as sound coming from the sides of the acoustic sensor device, is desired.

In at least some examples, the multiple sensor outputs of the acoustic sensor device may be mathematically combined to generate other desired directionality patterns, such as a cardioid pattern, a hyper-cardioid pattern, a super-cardioid pattern, or other suitable directionality pattern. Such directionality patterns may reject sound emanating from undesired directions, such as from the sides and the back of the acoustic sensor device, while improving sensitivity of the acoustic sensor device to sound emanating from desired directions, such as from the front of the acoustic sensor device. Because the directionality patterns are mathematically obtained based on combinations of directional and omnidirectional sensor outputs that are not dependent on frequency in a desired frequency range, such as the audible frequency range, the directionality patterns do not change, or only insignificantly change, over frequency. In some cases, other mathematical manipulations based on the dipole directional sensor output and the omnidirectional sensor output may additionally or alternatively be performed. For example, a multiplication of the two sensor outputs may be performed to determine sound intensity.

In some examples, the disclosed acoustic sensor device may provide the multiple sensor outputs and directionality patterns with a reduced number of sound ports as compared to systems in which respective separate acoustic sensor devices may be used to provide the sensor outputs. For example, the package of the acoustic sensor device may include two sensing elements and two sound ports. The two sensing elements may be positioned in the package such that a first side of a first sensing element and a first side of a second sensing element are exposed to the ambient environment via a first sound port in the package and a second side of the first sensing element is exposed to the ambient environment via a second sound port in the package. A second, opposing, side of the second sensing element is exposed to an air volume in the package that is effectively sealed from the ambient environment. In this configuration, the first sensing element exhibits a dipole directional pick-up pattern with respect to sound waves traveling in the ambient environment and the second sensing element exhibits an omnidirectional pick-up pattern with respect to the sound waves traveling in the ambient environment. In this example, because the first sound port of the acoustic sensor device exposes both a first side of the first sensing element and the first side of the second sensing element to the ambient environment, a dipole directional sensor output and an omnidirectional sensor output may be provided by the single acoustic sensor device equipped with only two sound ports. Thus, the different directionally patterns may be obtained from a single acoustic sensor device with a reduced number of sound ports as compared to systems in which multiple separate acoustic sensor devices, such as arrays of multiple separate acoustic sensor devices, may be utilized to create desired directionality patterns. For example, an array of a separate omnidirectional microphone and dipole microphone may have a total of three sound ports to achieve the same as the acoustic sensor device described.

The disclosed sensor devices equipped with multiple sensing elements may be useful in a wide variety of microphone applications and contexts, including, for instance, various consumer devices such as smartphones, laptops, and earbuds that include or are otherwise equipped with microphones. The configuration of the disclosed sensor devices equipped with multiple sensing elements may be useful in connection with any device in which, in some environments or situations, there is an interest in listening to sound originating from a specific direction with greater sensitivity than sound originating from other directions.

Although generally described in connection with microphones, the disclosed sensor devices equipped with multiple sensing elements may be used in other applications and contexts. For instance, the disclosed sensor devices equipped with multiple sensing elements are useful in connection with accelerometers, gyroscopes, inertial sensors, pressure sensors, gas sensors, etc. The disclosed sensor devices equipped with multiple sensing elements are described in the context of excitation by sound waves. However, alternative or additional stimuli may excite the sensing elements of the disclosed sensor devices in other contexts.

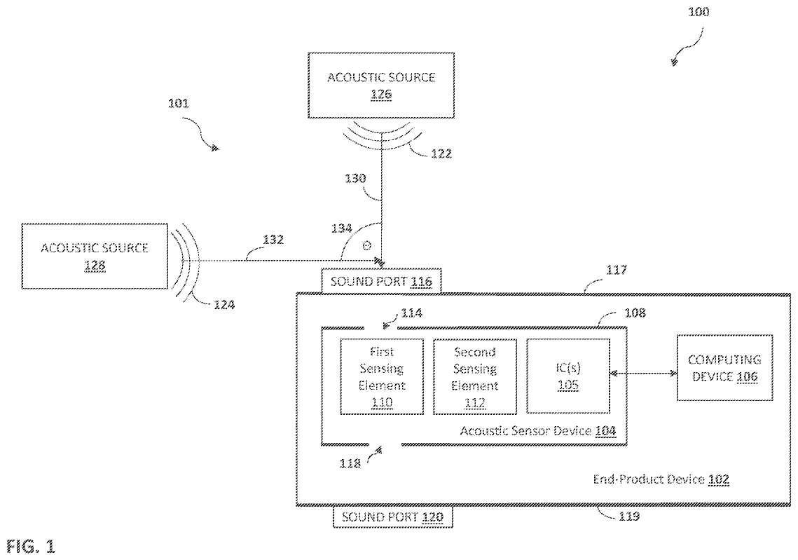

FIG. 1 is a block diagram of an acoustic sensing environment 100 in which an acoustic sensor device having multiple sensing elements may be utilized, in accordance with an example. An end-product device 102 equipped with an acoustic sensor device 104 may be placed in an ambient environment 101 (e.g., ambient air). The end-product device 102 may be an electronic device such as a smartphone, personal computer, headset, TV, robot, etc. The end-product device 102 may be further equipped with a computing device 106. The computing device 106 may be a processor of the end-product device, for example. Although the computing device 106 is illustrated in FIG. 1 as being a part of the end-product device 102 that is externally coupled to the acoustic sensor device 104, the computing device 106 may be external to the end-product device 102, in some examples. For example, the computing device 106 may be a processor of a computer or other electronic device that may be externally connected to the end-product device 102. In yet another, the computing device 106 may be internal to the acoustic sensor device 104 and/or at least a portion of functionality described herein with reference to the computing device 106 may be performed internally to the acoustic sensor device 104.

The acoustic sensor device 104 includes one or more transducers equipped with multiple sensing elements, including at least a first sensing element 110 and a second sensing element 112, packaged together in a package 108 of the acoustic sensor device 104. In various examples, the first sensing element 110 and the second sensing element 112 may be diaphragms or other sensing elements of separate transducers (e.g., MEMS transducers) that may be packaged together in the package of the acoustic sensor device 104, or may be separate diaphragms or other sensing elements formed in a single transducer (e.g., a single MEMS transducer) packaged in the package of the acoustic sensor device 104. For example, the first sensing element 110 may be a diaphragm of a first MEMS transducer formed on a first semiconductor die and positioned over a cavity formed in the first semiconductor die, and the second sensing element 112 may be a diaphragm of a second MEMS transducer formed on a second semiconductor die and positioned over a cavity formed in the second semiconductor die. In another example, the first sensing element and the second sensing element may be respective diaphragms of a single MEMS transducer formed on a single semiconductor die, there the first sensing element comprises 110 a first diaphragm positioned over a first cavity formed in the semiconductor die and the second sensing element 112 comprises a second diaphragm positioned over a second cavity formed in the semiconductor die, the second cavity being separated from the first cavity in the semiconductor die. In some examples, at least one of the first sensing element 110 and the second sensing element 112 may comprise a sensing element of a suitable transducer other than a MEMS transducer.

The first sensing element 110, the second sensing element 112, and the package 108 may be integrated together such that the first sensing element 110 and the second sensing element 112 exhibit different pick-up patterns with respect to sound waves traveling in the ambient environment 101. For example, as described in more detail below, the first sensing element 110, the second sensing element 112, and the package 108 may be integrated together such that the first sensing element 110 exhibits a dipole (or at least substantially dipole) directional pick-up pattern, with respect to sound waves traveling in the ambient environment 101 while the second sensing element exhibits an omnidirectional (or at least substantially omnidirectional) pick-up pattern with respect to the sound waves traveling in the ambient environment 101. Although the first sensing element 110 is generally described herein as exhibiting a dipole directional sensor output, it is noted that the first sensing element 110 exhibit a distorted dipole pick-up pattern or a directional pick-up pattern having a shape other than a dipole, in some examples.

In an example, the first sensing element 110 and the second sensing element 112 generally comprise a same structure. For example, both the first sensing element 110 and the second sensing element 112 may comprise a cantilever diaphragm structure that is attached on one end and is free to move on the other end. In another example, the first sensing element 110 and the second sensing element 112 may comprise different structures. The first sensing element 110 and the second sensing element 112 may comprise different structures that are optimized for, respectively, directional sensing operation and omnidirectional sensing operation, for example. As just an example, the first sensing element 110 may comprise a cantilever diaphragm structure that is attached on one end and is free to move on the other end, and the second sensing element 112 may comprise a fixed-fixed structure that is fixed on both ends, or vice versa. In another example, one or both of the first sensing element 110 and the second sensing element 112 may comprise a structure that is fixed on more than two sides, such as a diaphragm that is fixed or anchored on all sides around the perimeter. In other examples, the first sensing element 110 and/or the second sensing element 112 may comprise another suitable structure.

The acoustic sensor device 104 may include a first sound port 114 and a second sound port 118. The end-product device 102 may include a first sound port 116 and a second sound port 120. The first sound port 116 of the end-product device 102 may lay on or be otherwise embedded in an edge 117 of the end-product device 102. The second sound port 120 of the end-product device 102 may lay on or be otherwise embedded in an edge 119 of the end-produce device 102. An acoustic channel may be formed between the first sound port 116 of the end-product device 102 and the first sound port 114 of the acoustic sensor device 104. Similarly, an acoustic channel may be formed between the second sound port 118 of the acoustic sensor device 104 and the second sound port 120 of the end-product device 102. It is noted that although the first sound port 116 and the second sound port 120 of the end-product device 102 are illustrated in FIG. 1 as being on opposing edges 117, 119 of the end-product device 102, this need not be the case, and the first sound port 116 and the second sound port 120 may be differently arranged on the end-product device 102 in other examples. For example, the first sound port 116 and the second sound port 120 may both lay on, or otherwise be embedded into, a same edge of the end-product device 102, such as the edge 117.

The first sensing element 110 may be placed in the package of the acoustic sensor device 104 such that two opposing sides of the first sensing element 110 are exposed to the ambient environment 101. For example, a first side of the first sensing element 110 may be exposed to the ambient environment 101 via the first sound port 114 of the acoustic sensor device 104 and the first sound port 116 of the end-product device 102. Further, a second side of the first sensing element 110 may be exposed to the ambient environment 101 via the second sound port 118 of the acoustic sensor device 104 and the second sound port 120 of the end-produce device 102.

The second sensing element 112, on the other hand, may be placed in the package of the acoustic sensor device 104 such that only one side of the second sensing element 112 is exposed to the ambient environment 101 while the other, opposing, side of the of the second sensing element 112 is sealed from the ambient environment 101. For example, a first side of the second sensing element 112 may be exposed to the ambient environment 101 via the first sound port 114 of the acoustic sensor device 104 and the first sound port 116 of the end-product device 102. On the other hand, a second, opposing, side of the second sensing element 112 may be exposed to an air volume that is internal to the acoustic sensor device 104 and the end-producer device 102 and is sealed from the ambient environment 101. In some case, the second sensing element 112 may be exposed to an air volume that is internal to the acoustic sensor device 104 and the end-producer device 102 and is generally sealed from the ambient environment 101 but includes a vent hole or other small opening to equalize the direct current (DC), or low frequency, pressure changes in the ambient environment 101.

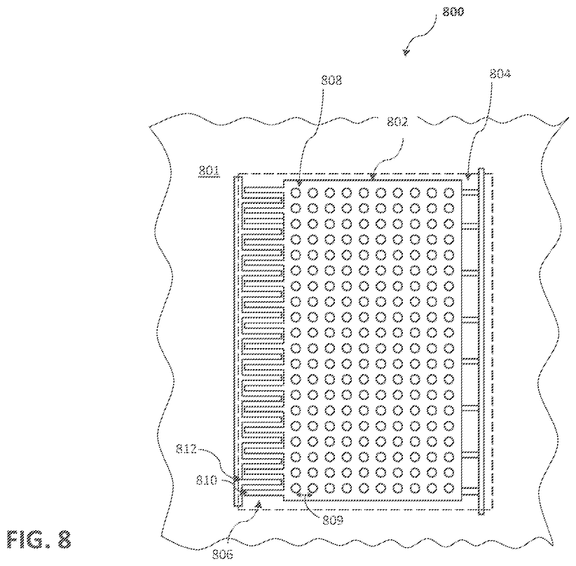

With continued reference to FIG. 1, sound waves 122 and 124 may be emitted by a first acoustic source 126 and a second acoustic source 128, respectively, and may travel therefrom in the ambient environment 101. As depicted, the sound waves 122 are propagated radially and include a direct path 130. Sound waves 124 are propagated radially and include a direct path 132 at an angle 134 from the direct path 130. Sound waves 122 thus travel along the path 130 that is parallel to the edges 117 and 119, while sound waves 124 travel along the path 132 that is perpendicular to the surfaces 117 and 119. When the sound waves 122 and 124 are captured by the acoustic sensor device 104, the sound waves 122 and 124 are differently captured by the first sensing element 110 and the second sensing element 112 of the acoustic sensor device 104. For example, in accordance with the arrangement of the first sensing element 110 in the package of the acoustic sensor device 104 as described above, the first sensing element 110 may exhibit a dipole, or FIG. 8, pick-up pattern with respect to sound waves traveling in the ambient environment 101. Thus, the first sensing element 110 may capture the portion of the ambient environment 101 with sound waves 124 parallel to the edges 117, 119 with decreased sensitivity relative to the portion of the ambient environment 101 with sound waves 122 perpendicular to the edges 117, 119. For example, the first sensing element 110 may capture sound waves 122 with at least 15 dB or 20 dB greater sensitivity than sound waves 124 at certain audible frequencies. Further, in accordance with the arrangement of the second sensing element 112 in the package of the sensor device 104 as described above, the second sensing element 112 may exhibit an omnidirectional pick-up pattern with respect to sound waves traveling in the ambient environment 101. Thus, the second sensing element 112 may capture the sound waves 122 and the sound waves 124 with at least substantially equal sensitivity.

The acoustic sensor device 104 also includes one or more integrated circuit (IC) devices 105. The one or more IC devices 105 may include one or more application specific integrated circuit (ASIC) devices, for example. The one or more IC devices 105 may be configured to read out electrical signals generated based on movement of the first sensing element 110 and the second sensing element 112, and to generate one or more sensor output signals based on the electrical signals. The one or more sensor output signals may include a first sensor output signal (sometimes referred to herein as a “directional sensor output signal”) corresponding to the pick-up pattern (e.g., the dipole pattern) exhibited by the first sensing element 110 and a second sensor output signal (sometimes referred herein as an “omnidirectional sensor output signal”) corresponding to the pick-up pattern exhibited by the second sensing element 112 (e.g., the omnidirectional pattern).

The one or more IC devices 105 may be configured to provide the one or more sensor output signals to the computing device 106. The computing device 106 may be configured to further process the one or more sensor output signals, in some examples. For example, the computing device 106 is configured to determine whether the directional sensor output signal or the omnidirectional sensor output signal should be used as an output of the acoustic sensor device 104. As another example, the computing device 106 is configured to mathematically combine the directional sensor output signal and the omnidirectional sensor output signal to generate a combined sensor output signal having a cardioid directionality pattern. In yet another example, the computing device 106 may be configured generate a weighted combination of directional sensor output signal and the omnidirectional sensor output signal to produce a combined sensor output signal having a hyper-cardioid or a super-cardioid directionality pattern. In other examples, the directional sensor output signal and the omnidirectional sensor output signal may be combined in other suitable manners to provide other suitable directionality patterns of the acoustic sensor device 104. In some aspects, the computing device 106 may be configured to additionally or alternatively perform other mathematical manipulations based on the directional sensor output signal and the omnidirectional sensor output signal. For example, the computing device 106 may be configured to multiply the directional sensor output signal with the omnidirectional sensor output signal to determine a sound intensity.

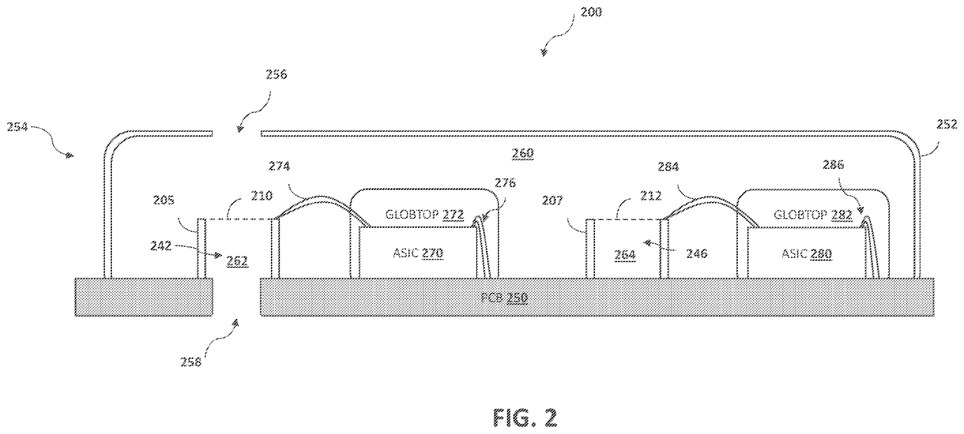

Turning now to FIG. 2, a cross-sectional, schematic view of an acoustic sensor device 200 having multiple sensing elements, according to an example, is depicted. The acoustic sensor device 200 may correspond to the acoustic sensor device 104 of FIG. 1. The acoustic sensor device 200 may be embedded in, or otherwise integrated with, an electronic device, such as the end-product device 102 of FIG. 1. The acoustic sensor device 200 may include a plurality of transducers, including at least a first transducer 205 and a second transducer 207. Each of the first transducer 205 and the second transducer 207 may be a MEMS transducer, for example. For ease of explanation, the first transducer 205 is sometimes referred to herein as a “first MEMS transducer 205” and the second transducer 207 is sometimes referred to herein as a “second MEMS transducer 207.” In other examples, however, the first transducer 205 and/or the second MEMS transducer 207 may comprise a suitable transducer other than a MEMS transducer.

The first MEMS transducer 205 and the second MEMS transducer 207 may be attached to or otherwise supported by a PCB or other substrate 250 (generally referred to herein as “PCB 250”). The PCB 250 may comprise one or more layers. In an example in which the PCB 250 comprises multiple layers, respective ones of the multiple layers may be separated from one another by a dielectric material. The one or more layers of the PCB 250 may include conductive traces that may route electrical signals in the PCB 250. The acoustic sensor device 200 may also include a lid or other enclosure 252 (generally referred to herein as “lid 252”). The lid 252 may be placed over the PCB 250 to enclose the components of the acoustic sensor device 200 mounted on or otherwise attached to the PCB 250. The lid 252 may be composed of, or otherwise include, a metal, plastic, ceramic, or other material. The lid 252 and the PCB 250 may form a package 254 of the acoustic sensor device 200. In other examples, a package of the acoustic sensor device 200 may be formed in other suitable manners.

The first MEMS transducer 205 may include a diaphragm or other sensing element 210 positioned over a cavity 242. The cavity 242 may be formed in the first MEMS transducer 205 through various microfabrication practices including, for instance, deep reactive ion etching (DRIE). The diaphragm 210 includes a first side that faces outwards with respect to the cavity 242 and a second side that faces the cavity 242. The second MEMS transducer 207 may include a diaphragm or other sensing element 212 positioned over a cavity 246. The cavity 246 may be formed in the second MEMS transducer 207 through various microfabrication practices including, for instance, deep reactive ion etching (DRIE). The diaphragm 212 includes a first side that faces outwards with respect to the cavity 246 and a second side that faces the cavity 246.

The acoustic sensor device 200 may include a first sound port 256 formed in the lid 252 and a second sound port 258 formed in the PCB 250. A first air volume 260 may be formed in the package 254 of the acoustic sensor device 200 between the PCB 250 and the lid 252 and may be exposed to the ambient environment via the first sound port 256. A second air volume 262 may comprise the cavity 242 in the first MEMS transducer 205. The first MEMS transducer 205 may be positioned in the package 254 over the second sound port 258 in the PCB 250 such that the first side of the diaphragm 210 faces the air volume 260 and the first sound port 256 and the second the diaphragm 210 faces the second sound port 258 in the PCB 250. The first sound port 256 may thus expose the first side of the diaphragm 210 of first MEMS transducer 205 to the ambient environment via the air volume 260 in the package 254. The second sound port 258 may expose the second side of the diaphragm 210 of the first MEMS transducer 205 to the ambient environment via the second air volume 262. The first MEMS transducer 205 may thus sense a pressure gradient between the opposing sides of the diaphragm 210 that are exposed to the ambient environment. Because the diaphragm 210 of the first MEMS transducer 205 has two opposing sides that are exposed to the ambient environment, and thus the first MEMS transducer 205 senses the pressure gradient between the opposing sides of the diaphragm 210 exposed to the ambient environment, the first MEMS transducer 205 produces a directional polar pattern. For example, the first MEMS transducer 205 may produce a dipole, or FIG. 8, polar pattern.

The second MEMS transducer 207 may be positioned in the package 254 such that only a single side of the diagram 212 of the second MEMS transducer 207 is exposed to the ambient environment. In an example, the second MEMS transducer 207 is positioned in the package 254 such that the first side of the diaphragm 212 faces the first air volume 260 and the first sound port 256 and the second MEMS transducer 207 sits over and faces a sealed portion of the PCB 250. An air volume 264 that may comprise the cavity 246 of the second MEMS transducer 207 may thus be sealed by the PCB 250 and not exposed to the ambient environment. In some cases, the air volume 264 is generally sealed from the ambient environment but the acoustic sensor device 200 may include a vent hole or other small opening (e.g., in the PCB 250) exposing the air volume 264 to the ambient environment to equalize the direct current (DC), or low frequency, pressure changes in the ambient environment. The first sound port 256 may thus expose the first side of the diaphragm 212 of second MEMS transducer 207 to the ambient environment via the air volume 260 in the package 254. The second side of the side of the diaphragm 212 of second MEMS transducer 207, on the other hand, may be placed over the air volume 264 that is sealed from the ambient environment. The second MEMS transducer 207 may thus sense pressure at the single exposed side of the second MEMS transducer 207 relative to a reference pressure in the sealed air volume 264. Because the diaphragm 212 of the second MEMS transducer 207 has only a single side that is exposed to the ambient environment, and thus senses the second MEMS transducer 207 senses pressure exerted on the single side that is exposed to the ambient environment, the second MEMS transducer 207 produces an omnidirectional polar pattern.

In various examples, the sensing element 210 of the first MEMS transducer 205 and the sensing element 212 of the second MEMS transducer 207 may comprise a same structure or may comprise structures that are different from each other. In some examples, the sensing element 210 of the first MEMS transducer 205 and the sensing element 212 of the second MEMS transducer 207 may comprise structures same as or similar to the structures (e.g., cantilever or fixed-fixed structures) described above in connection with the sensing elements 110, 112 of FIG. 1.

The acoustic sensor device 200 may also include a first ASIC 270 and a second ASIC 280. The first ASIC 270 and the second ASIC 280 may correspond to the one or more IC devices 105 in FIG. 1. Each of the first ASIC 270 and the second ASIC 280 may be mounted on or otherwise attached to the PCB 250. The first ASIC 270 may be covered by a globtop 272. The first ASIC 270 may be electrically coupled to the first MEMS transducer 205. For example, the first MEMS transducer 205 and first ASIC 270 may be electrically connected by wire bonds 274, either directly to each other, or via traces on the PCB 250. The first ASIC 270 may also be electrically connected to the PCB 250 by wire bonds 276. The second ASIC 280 may be covered by a globtop 282. The second ASIC 280 may be electrically coupled to the second MEMS transducer 207. For example, the second MEMS transducer 207 and second ASIC 280 may be electrically connected by wire bonds 284, either directly to each other, or via traces on the PCB 250. The second ASIC 280 may also be electrically connected to the PCB 250 by wire bonds 286. In other examples, the first transducer 205, the second transducer 207, the first ASIC 270, and/or the second ASIC 280 may be attached and/or electrically coupled using other suitable methods. For example, the first transducer 205 and/or the second transducer 207 may be attached to the PCB 250 using flip chip technology.

The first ASIC 270 may be configured to read out electrical signals generated by the first MEMS transducer 205 based on movement of the diaphragm 210 of the first MEMS transducer 205, and to generate a first sensor output based on the electrical signals read out from the first MEMS transducer 205. In an example, the first ASIC 270 may be configured to generate a dipole directional sensor output signal based on the electrical signals read out from the first MEMS transducer 205, the dipole directional sensor output having a dipole, or FIG. 8, directionality pattern. The second ASIC 280 may be configured to read out electrical signals generated by the second MEMS transducer 207 based on movement of the diaphragm 212 of the second MEMS transducer 207, and to generate a second sensor output based on the electrical signals read out from the second MEMS transducer 207. In an example, the second ASIC 280 may be configured to generate an omnidirectional sensor output signal based on the electrical signals read out from the second MEMS transducer 207.

The first sensor output generated by the first ASIC 270 and the second sensor output generated by the second ASIC 280 may be provided to a processor or other computing device, such as the computing device 106 in FIG. 1, for further processing and/or use by the processor or the other computing device. The processor or other computing device may determine whether the first sensor output signal or the second sensor output signal is to be used as the output of the acoustic sensor device 200, and/or may suitably combine the first sensor output signal and the second sensor output signal to generate a desired directionality pattern of the acoustic sensor device 200 as described herein. For example, the processor or other computing device may perform an unweighted or a weighted summation of the dipole directional sensor output signal and the omnidirectional sensor output signal to generate a combined sensor output signal corresponding to a cardioid, a hyper-cardioid, a super-cardioid, or another suitable directionality pattern. As another example, the processor or other computing device may multiply the dipole directional sensor output signal with the omnidirectional sensor output signal to determine intensity of the sound. In other examples, the processor or other computing device may perform other suitable manipulations of the dipole directional sensor output and/or the omnidirectional sensor output to achieve a desired directional pattern or other desired result.

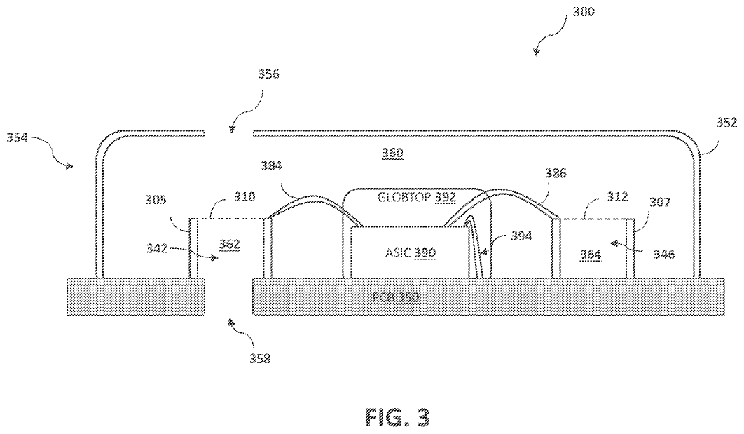

FIG. 3 is a cross-sectional, schematic view of an acoustic sensor device 300 having multiple transducers, according to another example. The acoustic sensor device 300 is generally the same as the acoustic device 200 of FIG. 2 and include like-numbered elements with the acoustic device 200 of FIG. 2 that are not discussed in detail below for the purpose of brevity. The acoustic sensor device 300 includes a first transducer (e.g., first MEMS transducer) 305 corresponding to the first transducer 205 of the acoustic sensor device 200 of FIG. 2 and a second transducer (e.g., second MEMS transducer) 307 corresponding to the second transducer 307 of the acoustic sensor device 200 of FIG. 2. The first MEMS transducer 305 and the second MEMS transducer 307 are attached to or otherwise supported by a PCB or other substrate 350 corresponding to the PCB 250 of the acoustic sensor device 200 of FIG. 2.

With reference to FIGS. 2 and 3, unlike two separate ASICs 270, 280 mounted to the PCB 205 in the acoustic sensor device 200 of FIG. 2, the acoustic sensor device 300 includes a single ASIC 390 mounted to the PCB 350 in the acoustic sensor device 300 of FIG. 3. The ASIC 390 may be covered by a globtop 392 and may be electrically coupled to both the first MEMS transducer 305 and the second MEMS transducer 307. For example, the ASIC 390 may be electrically connected by wire bonds 384 to the first MEMS transducer 305, either directly or via traces on the PCB 250. the ASIC 390 may also be electrically connected by wire bonds 386 to the second MEMS transducer 307, either directly or via traces on the PCB 350. The AISC 390 may further be electrically connected to the PCB 250 by wire bonds 394 to the PCB 350. The ASIC 390 may be configured to read out electrical signals generated by the first MEMS transducer 305 based on movement of the diaphragm 310 and the second MEMS transducer 307 based on movement of the diaphragm 312, and to generate a first, dipole directional, sensor output signal based on the output of the first MEMS transducer 305 and a second, omnidirectional, sensor output signal based on the output of the second MEMS transducer 307. The first sensor output signal and the second sensor output signal generated by the ASIC 390 may be provided to a processor or other computing device (e.g., the computing device 106 of FIG. 1) for further processing and/or use by the processor or the other computing device as described herein.

In some examples, the ASIC 390 may be configured to selectively provide one or both of the dipole directional sensor output signal and the omnidirectional sensor output signal to the processor or the other computing device, for example based on a control signal received by the ASIC 390 from the processor or the other computing device. The dipole directional sensor output signal or the omnidirectional sensor output signal may be dynamically selected by the control signal from the processor or the other computing device, for example. The processor or other computing device may be configured to determine whether the dipole directional sensor output signal or the omnidirectional sensor output signal is to be used as the output of the acoustic sensor device 300, and/or may suitably combine the dipole directional sensor output signal and the omnidirectional sensor output signal to generate a desired directionality pattern of the acoustic sensor device 300 as described herein.

In some examples, at least some further processing of the dipole directional sensor output and the omnidirectional sensor output of the acoustic sensor device 300 may be performed by the ASIC 390 internally to the acoustic sensor device 300. For example, the ASIC 390 may be configured to perform an unweighted or a weighted summation of the dipole directional sensor output signal and the omnidirectional sensor output signal to generate a combined sensor output having a cardioid, a hyper-cardioid, a super-cardioid, or another suitable directionality pattern under control of the processor or other computing device. In an example, the ASIC 390 may be configured to selectively provide one or more of i) the dipole directional sensor output signal, ii) the omnidirectional sensor output signal, and ii) a combined sensor output signal to the processor or the other computing device, for example based on a control signal received by the ASIC 390 from the processor or the other computing device. The dipole directional sensor output signal, the omnidirectional sensor output signal, or the combined sensor output signal may be dynamically selected by the control signal from the processor or the other computing device, for example. As another example, the ASIC 390 may be configured to multiply the dipole directional sensor output and the omnidirectional sensor output to determine intensity of the sound and provide the determined intensity of the sound to the processor or other computing device. In other examples, the ASIC 390 may be configured to perform other suitable manipulations of the dipole directional sensor output and/or the omnidirectional sensor output to achieve a desired directional pattern or other desired result.

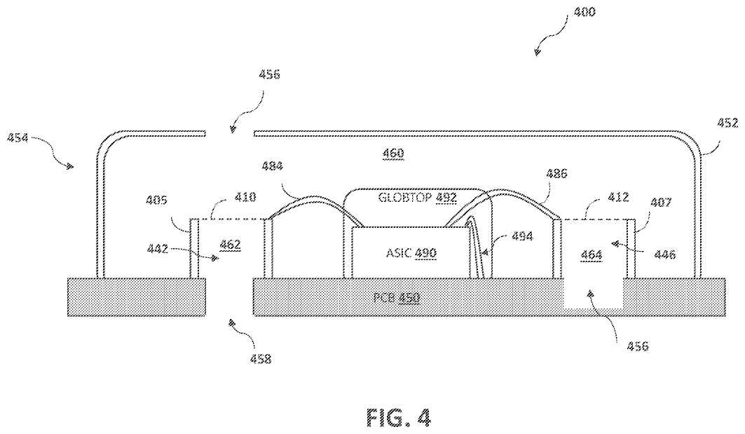

Turning now to FIGS. 4-6, several examples of acoustic sensor devices with enlarged sealed air volumes, in accordance with some examples, are illustrated. In traditional omnidirectional MEMS transducers, a sound port that couples one side of a diaphragm of the transducer to the ambient environment may be formed in a PCB or other substrate to which the MEMS transducer is attached, underneath a cavity of the MEMS transducer, thus coupling the side that of the diaphragm that faces the cavity of the MEMS transducer to the ambient environment. A second, generally larger, sealed air volume is formed in the package of the acoustic sensor device between the PCB and a lid, for example, to provide a reference pressure needed for a desired sensitivity, or a desired signal to noise ratio (SNR), of the omnidirectional MEMS transducer. In examples described herein, on the other hand, the second transducer is placed in the package of the acoustic sensor device such that a top side of the sensing element of the second transducer is exposed to the ambient environment via an air volume that is shared between the first transducer and the second transducer in the package of the acoustic sensor device. Such placement of the second transducer in the package of the acoustic sensor device allows for the first sound port to be shared between the first transducer and the second transducer in the acoustic sensor device. However, in this case, the sealed air volume that provides the reference pressure for the sensing element of the second transducer is limited to the cavity that is formed in the second transducer. The size of such air volume that provides the reference pressure for the sensing element of the second transducer may not be sufficiently large to ensure a desired sensitivity, or a desired SNR, of the second transducer, in some designs. Thus, in some examples, acoustic sensor devices and packaging may be designed to extend or otherwise enlarge the sealed air volume that provides the reference pressure for the sensing element of the second transducer.

Several examples with extended, or otherwise enlarged, sealed air volumes, according to some embodiments, are described in more detail below with reference to FIGS. 4-6. It is noted that although the examples of FIGS. 4-6 are generally described in the context of an acoustic sensor device that includes two transducers and a single ASIC, same or similar designs may be used to extend or enlarge the sealed air volume that provides the reference pressure for an omnidirectionally configured sensing element in an acoustic sensor device that includes multiple ASICs (such as the acoustic sensor device 200 of FIG. 2) and/or in an acoustic sensor device that includes a single transducer with multiple sensing elements.

FIG. 4 is a cross-sectional, schematic view of an acoustic sensor device 400 having multiple sensing elements and an enlarged sealed air volume, in accordance with an example. The acoustic sensor device 400 is generally the same as the acoustic device 300 of FIG. 3 and includes like-numbered elements with the acoustic device 300 of FIG. 3 that are not discussed in detail below for the purpose of brevity. The acoustic sensor device 400 includes a first transducer (e.g., first MEMS transducer) 405 corresponding to the first transducer 305 of the acoustic sensor device 300 of FIG. 3 and a second transducer (e.g., second MEMS transducer) 407 corresponding to the second transducer 307 of the acoustic sensor device 300 of FIG. 3. The first MEMS transducer 405 and the second MEMS transducer 407 are attached to or otherwise supported by a PCB or other substrate 450 corresponding to the PCB 350 of the acoustic sensor device 300 of FIG. 3.

The second MEMS transducer 407 includes a diaphragm 412 corresponding to the diaphragm 312 of the acoustic sensor device 300 of FIG. 3 and a cavity 446 corresponding to the cavity 346 of the acoustic sensor device 300 of FIG. 3. A portion of the PCB 450 over which the cavity 446 of the second MEMS transducer 407 is positioned includes an opening 456 formed therein. The acoustic sensor device 400 includes a sealed air volume 464 that comprises the cavity 446 of the second MEMS transducer 407 and the opening 456 formed in the PCB 450. The sealed air volume 464 of the acoustic sensor device 400 thus extends into the opening 456 formed in the PCB 450. The opening 456 may have a length that is less than, the same as, or greater than a length of the cavity 446 of the second MEMS transducer 407, in various examples. The opening 456 may have a width that is less than, the same as, or greater than a width of the cavity 446 of the second MEMS transducer 407, in various examples. In an example, the opening 456 does not extend entirely through the depth of the PCB 450. In another example, the opening 456 may extend entirely through the PCB 450 and may be sealed with a gasket placed at the opening 456 in the PCB 450.

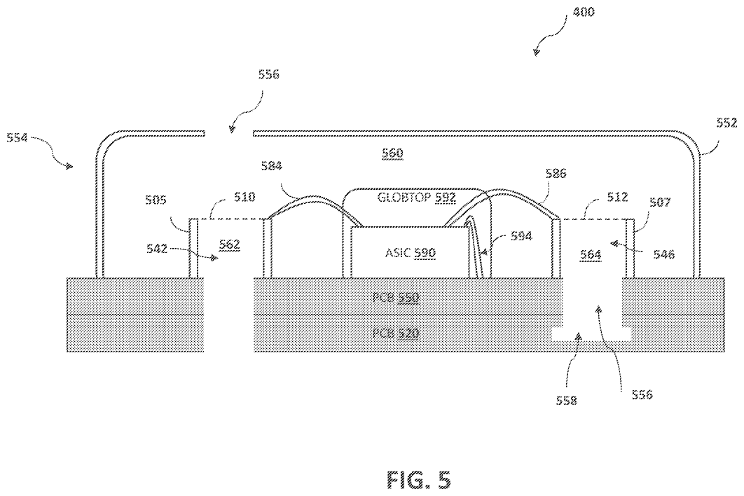

FIG. 5 is a cross-sectional, schematic view of an acoustic sensor device 500 having multiple sensing elements and an enlarged sealed air volume, in accordance with an example. The acoustic sensor device 500 is generally the same as the acoustic device 400 of FIG. 4 and includes like-numbered elements with the acoustic device 400 of FIG. 4 that are not discussed in detail below for the purpose of brevity. The acoustic sensor device 500 includes a first transducer (e.g., first MEMS transducer) 505 corresponding to the first transducer 405 of the acoustic sensor device 400 of FIG. 4 and a second transducer (e.g., second MEMS transducer) 507 corresponding to the second transducer 407 of the acoustic sensor device 400 of FIG. 4. The first MEMS transducer 505 and the second MEMS transducer 507 are attached to or otherwise supported by a PCB or other substrate 550 corresponding to the PCB 450 of the acoustic sensor device 400 of FIG. 4.

The second MEMS transducer 507 includes a diaphragm 512 corresponding to the diaphragm 412 of the acoustic sensor device 400 of FIG. 4 and a cavity 546 corresponding to the cavity 446 of the acoustic sensor device 400 of FIG. 4. A portion of the PCB 550 over which the cavity 546 of the second MEMS transducer 507 is positioned in the acoustic sensor device 500 includes an opening 556. The opening 556 is generally the same as or similar to the opening 456 of FIG. 4 except that the opening 556 extends through the entire depth of the PCB 550. The acoustic sensor device 500 includes an air volume 564 that comprises the cavity 546 of the second MEMS transducer 507 and the opening 556 of the PCB 550.

The PCB 550 is attached to or otherwise supported by a PCB or other substrate 520 of an end-product device. The PCB 520 includes an opening 558 formed therein underneath the opening 556 in the PCB 550. The opening 558 in the PBC 520 may have a length that is less than, the same as, or greater than a length of the opening 556 in the PCB 550, in various examples. The opening 558 in the PBC 520 may have a width that is less than, the same as, or greater than a width of the opening 556 in the PCB 550, in various examples. The opening 558 does not extend entirely through the depth of the PCB 520 and may be sealed, for example, with a gasket paced in the opening 558 in the PCB 520. The air volume 664 of the acoustic sensor device 500 may thus extend further into the sealed opening 558 in the PCB 520.

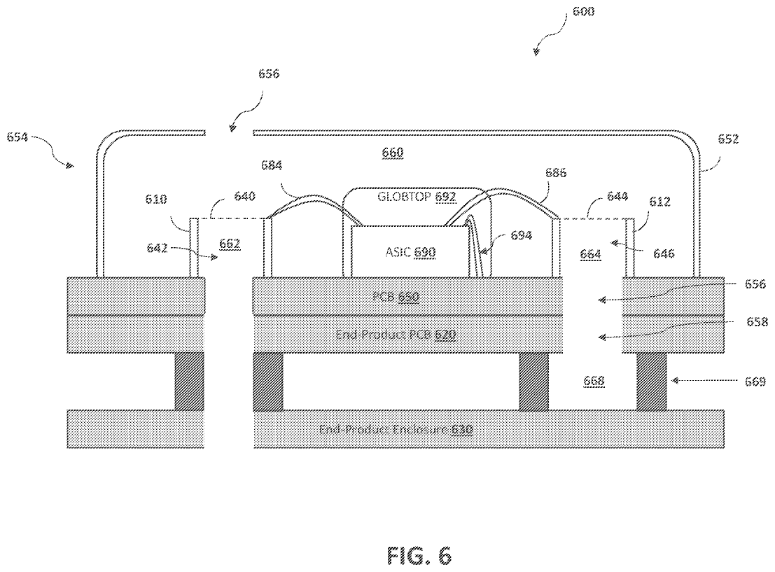

FIG. 6 is a cross-sectional, schematic view of an acoustic sensor device 600 having multiple sensing elements and an enlarged sealed air volume, in accordance with another example. The acoustic sensor device 600 is generally the same as the acoustic device 500 of FIG. 5 and includes like-numbered elements with the acoustic device 500 of FIG. 5 that are not discussed in detail below for the purpose of brevity. The acoustic sensor device 600 includes a first transducer (e.g., first MEMS transducer) 605 corresponding to the first transducer 505 of the acoustic sensor device 500 of FIG. 5 and a second transducer (e.g., second MEMS transducer) 607 corresponding to the second transducer 507 of the acoustic sensor device 500 of FIG. 5. The first MEMS transducer 605 and the second MEMS transducer 607 are attached to or otherwise supported by a PCB or other substrate 650 corresponding to the PCB 550 of the acoustic sensor device 500 of FIG. 5.

The second MEMS transducer 607 includes a diaphragm 612 corresponding to the diaphragm 512 of the acoustic sensor device 500 of FIG. 5 and a cavity 646 corresponding to the cavity 546 of the acoustic sensor device 500 of FIG. 5. A portion of the PCB 650 over which the cavity 646 of the second MEMS transducer 607 is positioned includes an opening 656 that extends through the entire depth of the PCB 650. The PCB 650 is attached to or otherwise supported by a PCB or other substrate 620 of an end-product device. The PCB 620 includes an opening 632, underneath the opening 656 in the PCB 650, that extends through the entire depth of the PCB 620. An air volume 668 is formed in a package of the end-product device, between the PCB 620 and an enclosure 630 of the end-product device. The air volume 668 is positioned underneath the opening 658 in the PCB 620 and is sealed off by one or more gaskets 669 in the package of the end-product device. The sealed air volume that provides the refence pressure to the diaphragm 612 of the second transducer 607 of the acoustic sensor device 600 thus extends further into the air volume formed in the package of the end-product device.

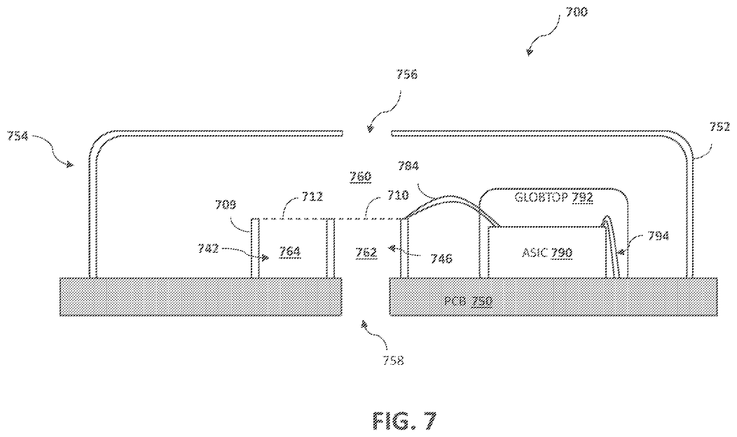

FIG. 7 is a cross-sectional, schematic view of an acoustic sensor device 700 having multiple sensing elements that exhibit different directionality patterns, in accordance with an example. The acoustic sensor device 700 is generally the same as the acoustic device 300 of FIG. 3 and includes like-numbered elements that are generally not discussed in detail for the purpose of brevity. The acoustic sensor device 700 includes a single transducer 709 and an ASIC 790 attached to or otherwise supported by a PCB or other substrate 750. The ASIC 790 may be covered by a globtop 792. The ASIC 790 may be electrically coupled to the MEMS transducer 709. For example, the ASIC 790 may be electrically connected by wire bonds 784 to the MEMS transducer 709, either directly or via traces on the PCB 750. The ASIC 790 may be electrically connected by wire bonds 794 to the PCB 750. The acoustic sensor device 700 may also include a lid or other enclosure 752 (referred to herein as “lid 752”).

The MEMS transducer 709 may include a first cavity 762 and a second cavity 764 formed therein. The cavities 762, 764 may be formed in the first MEMS transducer 205 through various microfabrication practices including, for instance, deep reactive ion etching (DRIE). The cavities 762, 764 may be separated from each other by substrate material of the MEMS transducer 709. The MEMS transducer 709 may also include a first sensing element (e.g., a first diaphragm) 710 positioned over the first cavity 762 and a second sensing element (e.g., a second diaphragm) 712 positioned over the second cavity 764. The MEMS transducer 709 may be placed in the package 754 of the acoustic sensor device 700 such that opposing sides the first diaphragm 710 of the MEMS transducer 709 are both exposed or otherwise coupled to an ambient environment while only one side of the second diaphragm 712 of the MEMS transducer 709 is exposed to the ambient environment.

The acoustic sensor device 700 may include a first sound port 756 formed in the lid 752 and a second sound port 758 formed in the PCB 750. A first air volume 760 may be formed in the package 754 of the acoustic sensor device 700 between the PCB 750 and the lid 752. The first air volume 760 may be exposed to the ambient environment via the first sound port 756. A second air volume 764 may comprise the cavity 742 of the MEMS transducer 709. A third air volume 762 may comprise the cavity 746 of the MEMS transducer 709. The MEMS transducer 702 may be positioned on the PCB 750 such that the cavity 746 of the MEMS transducer 709 sits over the second sound port 758 in the PCB 750 and the cavity 742 of the MEMS transducer 709 sits over a sealed portion of the PCB 750. Thus, a first side of the first sensing element 710 and a first side of the second sensing element 712 of the MEMS transducer 709 are exposed to the ambient environment via the first sound port 756 and the air volume 760. A second, opposing, side of the first sensing element 710 of the MEMS transducer 709 is exposed to the ambient environment via the second sound port 758 and the second air volume 764. The MEMS transducer 709 may thus sense a pressure gradient between the opposing sides of the first sensing element 710 of the MEMS transducer 709. On the other hand, a second, opposing, side of the second sensing element 712 faces the third air volume 764 that is sealed and is not exposed to the ambient environment. The MEMS transducer 709 may thus sense pressure at the single exposed side of the second sensing element 712 of the MEMS transducer 709 relative to a reference pressure in the sealed air volume 764.

In some examples, the size of the sealed air volume 764 may be increased to improve sensitivity of the second sensing element 712. For example, the sealed air volume 764 may be extended into an opening formed in the PCB 750 as described above with reference to FIG. 4. As another example, the sealed air volume 764 may be further extended into an opening formed in an end-product PCB to which the PCB 750 is attached, as described above with reference to FIG. 5. As yet another example, the sealed air volume 764 may be further still extended into a sealed air volume that may be formed in a package of the end-product device, as described above with reference to FIG. 6.

Because the first sensing element 710 of the MEMS transducer 709 has two opposing sides that are exposed to the ambient environment, and thus the MEMS transducer 709 senses the pressure gradient between the opposing sides of the sensing element 710 exposed to the ambient environment, the movement of first sensing element 710 of the MEMS transducer 709 produces a directional polar pattern. For example, the movement of first sensing element 710 of the MEMS transducer 709 produces a dipole, or FIG. 8, polar pattern. On the other hand, because the second sensing element 712 of the MEMS transducer 709 has only a single side that is exposed to the ambient environment, and thus the MEMS transducer 709 senses pressure exerted on the single side of the second sensing element 712 that is exposed to the ambient environment, movement of the second sensing element 712 of the MEMS transducer 709 produces an omnidirectional polar pattern.

In various examples, the first sensing element 710 and the second sensing element 712 of the MEMS transducer 709 may comprise a same structure or may comprise structures that are different from each other. In some examples, the first sensing element 710 and the second sensing element 712 of the MEMS transducer 709 may comprise structures same as or similar to the structures (e.g., cantilever or fixed-fixed structures) described above (e.g., in connection with the sensing elements 110, 112 of FIG. 1).

The ASIC 790 may be configured to read out and process one or more electrical signals from the MEMS transducer 709, a generate one or more sensor output signals based on the one or more electrical signals read out from the MEMS transducer 709. In an example, the ASIC 790 is configured to read out a first electrical signal generated based on the movement of the first sensing element 710 in the MEMS transducer 709 and a second electrical signal generated based on the movement of the second sensing element 712 in the MEMS transducer 709. In some examples, electrodes of the first sensing element 710 and electrodes of the second sensing element 712 may be electrically connected through metal layers that may be included in the semiconductor die of the transducer 709 such that the ASIC 790 may read out the first electrical signal generated based on the movement of the first sensing element 710 in the MEMS transducer 709 and the second electrical signal generated based on the movement of the second sensing element 712 in the MEMS transducer 709 via a same electrical connection between the ASIC 790 and the MEMS transducer 709. The ASIC 790 may be configured to perform further operations based on the first electrical signal and the second read out from the MEMS transducer 709. For example, the ASIC 790 may be configured to perform operations same as or similar to those described above in connection with the ASIC 390 of FIG. 3.

FIG. 8 is a top, schematic view of an example transducer structure having a transducer 800 formed in a semiconductor die in accordance with an example. The transducer 800 may correspond to any of the transducers 205, 207, 305, 307, 405, 407, 505, 507, 605, 607 described above with reference to FIGS. 2-6, in various examples. The transducer 800 includes a sensing element, such as movable membrane or diaphragm, 802 (sometimes referred to herein as “diaphragm 802”) that is attached to a surrounding substrate 801 of the semiconductor die on one end by one or multiple anchors 804. The substrate 801 has a cavity 806 above which the diaphragm 802 is positioned. The cavity 806 may be formed through various microfabrication practices including, for instance, deep reactive ion etching (DRIE). The diaphragm 802 may be configured as a plate. In an example, the diaphragm 802 may include one or more holes 808. The holes have a spacing 809 between them. In this manner, the diaphragm 802 is considered a porous plate. In other examples, the diaphragm 802 is nonporous. For example, the diaphragm 802 may be configured as a solid plate that omits the holes 809.

Attached to the free edges of diaphragm 802 are one or more fingers 810. The fingers 810 are configured so that the fingers move with the diaphragm 802. The diaphragm 802 and fingers 810 may thus be considered a single composite moving structure. This moving structure includes at least one conductive layer.

The transducer 800 may also include fingers 812 fixed to the substrate 801. As the transducer 800 is excited by a sound wave, the fixed fingers 812 do not move, or move relatively less than fingers 810. Fingers 812 include at least one conductive layer such that a capacitance is formed between fingers 810 and 812. As the diaphragm 802 moves (e.g., vibrates), the gap between fingers 810 and 812 changes. This creates a change in capacitance between fingers 810 and 812 that can be converted into an electronic signal by an ASIC, for example.

The anchors 804 may be configured as, or otherwise include, a single anchor that extends across the width of diaphragm 802, a single anchor with a width less than that of diaphragm 802, or multiple anchors with widths less than diaphragm 802. The top view profile of the anchors 802 may be rectangular, elliptical, triangular, or any other geometrical shape. In some examples, one or more of the anchors 804 may include fillets, or curved corners, at the connection point between the anchor 804 and diaphragm 802 and/or the connection between the anchor 802 and surrounding substrate 801. In some examples, the thickness of the anchors 804 may be greater than the thickness of the diaphragm 802. Similarly, one or more of the anchors 804 may have different thicknesses and/or widths from one another. The transducer 800 may be designed such that the transducer has a first resonant frequency in the audio band. For example, the first resonant frequency of the transducer 800 may fall in a range from about 1 kHz to about 5 kHz. Additionally, the transducer 800 may have a second resonant frequency that is outside of the audio band (e.g., greater than 20 kHz).

The diaphragm 802 is illustrated as a rectangle for ease of illustration. The diaphragm 802 may have a top profile that is rectangular, circular, elliptical, triangular, or any other geometrical shape. Similarly, the cavity 806 may have a top profile that is rectangular, circular, elliptical, triangular, or any other geometrical shape. The fingers 810 may cover the entire perimeter of the free ends of the diaphragm 802 or one or more smaller subsections. The fingers 810 may have a thickness that is different than the thickness of diaphragm 802 and/or fingers 812. The fingers 810 and/or 812 may have a top profile that is rectangular, circular, elliptical, triangular, or any other geometrical shape. In some examples, the gap between the fingers 810 and 812 may fall in a range from about 1 um to about 8 um, the length of fingers 810 and 812 may fall in a range from about 50 um to about 250 um, and the width of fingers 810 and 812 may fall in a range from about 1 um to about 20 um. In other examples, the length and/or width of fingers 810 and/or 812 may vary relative to one another. For example, the fingers 810 and/or 812 on at least one of the free sides of diaphragm may have a different length than the remaining sides. In some examples, the gap of at least one set of fingers 810 and 812 along the perimeter of diaphragm 802 may be different than that of another set of fingers. In some examples, the diaphragm 802 may include two or more diaphragms that are coupled electrically and/or mechanically.

In some examples, the spacing 809 between each of the holes 808 may be equal to the diameter of the holes 808. In other examples, the spacing 809 between each of the holes 808 may be less than or greater than the diameter of the holes 808. The spacing 809 may be determined as a ratio of the diameter of the holes 808. For example, the spacing 809 may be half, twice, three times, or four times the diameter of the holes 808. In some examples, the holes 808 may have a diameter that falls in a range from about 2 um to about 60 um and the spacing 809 may fall in a range from about 2 um to about 100 um. In one example, the holes 808 have a diameter of 4 um and the spacing 809 between the holes is 8 um. In yet another example, the holes 808 may vary in size and/or spacing from one another. For example, at least one of the holes 808 may be smaller than another hole on diaphragm 802. The holes 808 may cover the entire surface of diaphragm 802 or one or multiple subsections of diaphragm 802. Furthermore, the holes 808 may have a profile that is rectangular, circular, elliptical, triangular, hexagonal, or any other geometrical shape.

In some examples, the transducer 800 may be configured differently depending on whether the transducer 800 is to be placed in a package of an acoustic sensor device such that the transducer 800 exhibits a directional pick-up pattern or an omnidirectional pick-up pattern. For example, the transducer 800 may be configured as discussed above when the transducer 800 is placed in a package of an acoustic sensor device to exhibit a directional pick-up pattern. On the other hand, if the transducer 800 is to be placed in a package of an acoustic sensor device to exhibit an omnidirectional pick-up pattern, the transducer 800 may comprise a parallel plate structure with a moving diaphragm and at least one fixed backplate suspended above or below the moving diaphragm.

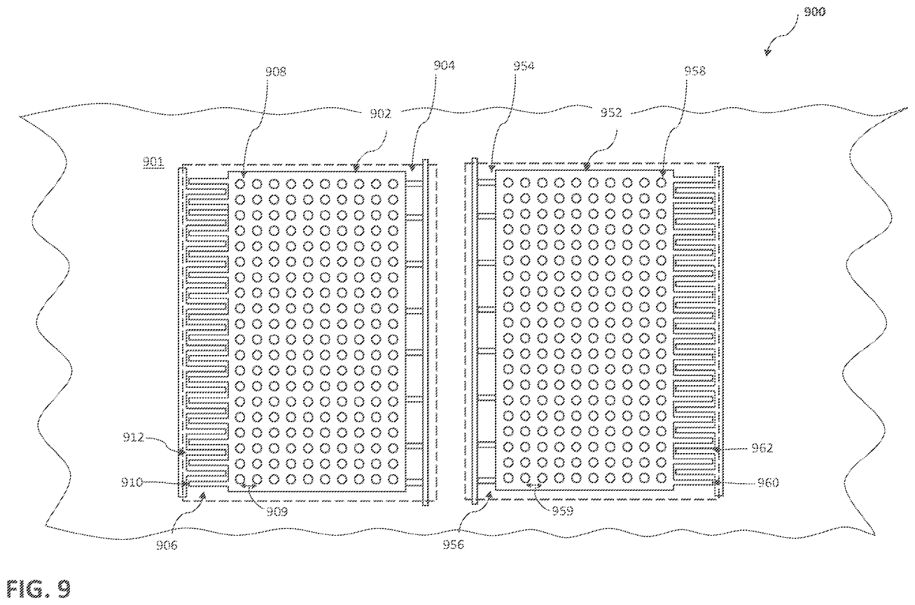

FIG. 9 is a top, schematic view of a transducer 900 having multiple sensing elements, in accordance with an example. The transducer 900 may correspond to the transducer 700 of FIG. 7, in various examples. The transducer 900 may include a first sensing element, such as movable membrane or diaphragm, 902 (sometimes referred to herein as “diaphragm 902”) that may be attached to a surrounding substrate 901 of the semiconductor die on one end by one or multiple anchors 904. The transducer 900 may also include a second sensing element, such as movable membrane or diaphragm, 952 (sometimes referred to herein as “diaphragm 952”) that may be attached to the surrounding substrate 901 of the semiconductor die on one end by one or multiple anchors 954. The substrate 901 have two separate cavities 906, 956 formed therein. The diaphragm 902 is positioned over the cavity 906 and the diaphragm 952 is positioned above the cavity 956. The cavities 906, 956 may be formed through various microfabrication practices including, for instance, deep reactive ion etching (DRIE).

Each of the diaphragms 902, 952 may be configured as a plate. In an example, the diaphragm 902 may include one or more holes 908 and the diaphragm 952 may include one or more holes 958. The holes 908 have a spacing 909 between them. The holes 958 have a spacing 959 between them. In this manner, each of the diaphragms 902, 952 is considered a porous plate. In other examples, at least one of the diaphragms 902, 952 is nonporous. For example, the diaphragm 902 may be configured as a solid plate that omits the holes 909 and the diaphragm 904 may be configured as a solid plate that omits the holes 959. In an example, one of the diaphragms 902, 952 may be a porous plate while the other one of the diaphragms 902, 952 may be a nonporous plate.

The transducer 900 may include one or more fingers 910 attached to the free edges of the first diaphragm 902 and one or more fingers 960 attached to the free edges of the second diaphragm 952. The transducer 900 may include one or more fingers 912 and 962 fixed to the substrate 901. The fingers 910, 912 and the fingers 960, 962 may be configured as described above in connection with fingers 810, 812 od FIG. 8 to create a change capacitance with movement of, respectively, the diaphragm 902 and the diaphragm 952 The change in capacitance can be converted into an electronic signal by an ASIC, for example.

The anchors 904, 954 may generally be the same as or similar to the anchors 804 of the transducer 800 of FIG. 8. For example, each of the anchors 904, 954 may be configured as, or otherwise include, a single anchor or multiple anchors as described above with respect to the anchors 804 of the transducer 800 of FIG. 8.

In some examples, one of the first diaphragm 902 or the second diaphragm 952 may comprise a different structure from the structure described above. For example, one of the first diaphragm 902 or the second diaphragm 952 may be configured as a parallel plate structure with a moving diaphragm and at least one fixed backplate suspended above or below the moving diaphragm.

Described above are a number of examples of acoustic sensor devices equipped with multiple sensing elements. The multiple sensing elements are positioned in a package of an acoustic sensor device such that respective ones of the sensing elements have different pick-up patterns with respect to direction of travel of sound waves in an ambient environment around the acoustic sensor device. For example, an acoustic sensor device may include a first sensing element positioned in the package such that the first sensing element exhibits a directional pick-up pattern and a second sensing element positioned in the package such that the second sensing element exhibits at least substantially omnidirectional pick-up pattern. The multiple sensor outputs of the acoustic sensor device may be selectively used depending on an environment of the acoustic sensor device or a purpose of use of the acoustic sensor device. Additionally or alternatively, the multiple sensor outputs may be mathematically combined to produce other desired directionality patterns of the acoustic sensor device and/or further manipulated, for example to determine intensity of sound. In various example configurations described above, the directional pick-up pattern of the first sensing element and the at least substantially omnidirectional pick-up pattern of the second sensing element may be achieved with only two sound ports formed in the package of the acoustic sensor device.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An acoustic sensor device, comprising:
a package;
a substrate disposed in the package or forming a part of the package; and
one or more microelectromechanical system (MEMS) transducers supported by the substrate and packaged in the package, the one or more MEMS transducers including a plurality of sensing elements including at least a first sensing element and a second sensing element, wherein the one or more MEMS transducers are positioned in the package such the first sensing element exhibits a first directionality pick-up pattern with respect to sound waves traveling in an ambient environment of the acoustic sensor device and the second sensing element exhibits a second directionality pick-up pattern with respect to the sound waves traveling in the ambient environment of the acoustic sensor device, wherein the second directionality pick-up pattern is different from the first directionality pick-up pattern.

2. The acoustic sensor device of claim 1, wherein the one or more MEMS transducers are placed in the package such that the first sensing element exhibits a dipole directional pick-up pattern and the second sensing element exhibits an omnidirectional pick-up pattern.

3. The acoustic sensor device of claim 2, further comprising:
a first air volume formed in the package on a first side of the first sensing element;
a first sound port formed in the package of the acoustic sensor device, the first sound port configured to expose the first side of the first sensing element to the ambient environment via the first air volume;
a second air volume formed in the package on a second side of the first sensing element, the second side being of the first sensing element being opposite the first side of the first sensing element; and
a second sound port formed in the package, the second sound port configured to expose the second side of the first sensing element to the ambient environment via the second air volume.

4. The acoustic sensor device of claim 3, wherein:
the first sound port is configured to further expose a first side of the second sensing element to the ambient environment via the first air volume, and
the acoustic sensor device further comprises a sealed air volume formed at least partially in the package of the acoustic sensor device on a second side of the second sensing element, the second side of the second sensing element being opposite the first side of the second sensing element.

5. The acoustic sensor device of claim 4, wherein:
the second sensing element is formed on a semiconductor die, and
the sealed air volume comprises a cavity in the semiconductor die underneath the second sensing element.

6. The acoustic sensor device of claim 5, wherein:
the semiconductor die is placed on the substrate of the acoustic sensor device, and
the substrate of the acoustic sensor device includes an opening formed therein underneath the cavity in the semiconductor die such that the sealed air volume extends into the opening in the substrate of the acoustic sensor device.

7. The acoustic sensor device of claim 6, wherein the sealed air volume is configured to further extend into a cavity formed in a substrate of an end product device into which the acoustic sensor device is integrated.

8. The acoustic sensor device of claim 7, wherein the sealed air volume further is configured to further extend into a sealed air volume formed in a package of the end product device into which the acoustic sensor device is integrated.

9. The acoustic sensor device of claim 1, wherein the one or more MEMS transducers include a first MEMS transducer including the first sensing element and a second MEMS transducer including the second sensing element, wherein the first MEMS transducer is formed in a first semiconductor die and the second MEMS transducer is formed in a second semiconductor die separate from the first semiconductor die.

10. The acoustic sensor device of claim 1, wherein the one or more MEMS transducers include a single MEMS transducer formed on a semiconductor die, the single MEMS transducer including
the first sensing element,
a first cavity formed in the semiconductor die underneath the first sensing element,
the second sensing element, and
a second cavity formed in the semiconductor die underneath the second sensing element, the second cavity being separated from the first cavity in the semiconductor die.

11. The acoustic sensor device of claim 1, further comprising one or more integrated circuit (IC) devices disposed in the package and electrically coupled to the one or more MEMS transducers, the one or more IC devices configured to read out and process a first electrical signal generated based on movement of the first sensing element and a second electrical signal generated based on movement of the second sensing element, the first electrical signal corresponding to the first directionality pick-up pattern exhibited by the first sensing element and the second electrical signal corresponding to the second directionality pick-up pattern exhibited by the second sensing element.

12. The acoustic sensor device of claim 11, wherein
the one or more MEMS transducers include a first MEMS transducer including the first sensing element and a second MEMS transducer including the second sensing element, and
the one or more IC devices include:
a first application specific integrated circuit (ASIC) electrically coupled to the first MEMS transducer, the first ASIC configured to read out and process the first electrical signal generated based on the movement of the first sensing element of the first MEMS transducer, and
a second ASIC electrically coupled to the second MEMS transducer, the second ASIC configured to read out and process the second electrical signal generated based on the movement of the second sensing element of the second MEMS transducer.

13. The acoustic sensor device of claim 11, wherein the one or more IC devices include an application specific integrated circuit (ASIC) configured to read out and process both the first electrical signal generated based on the movement of the first sensing element and the second electrical signal generated based on the movement of the second sensing element.

14. The acoustic sensor device of claim 12, wherein the ASIC is configured to selectively generate one or more of i) a first sensor output signal based on the first electrical signal generated based on the movement of the first sensing element, the first sensor output signal corresponding to the first directionality pick-up pattern exhibited by the first sensing element ii) a second sensor output signal based on the second electrical signal generated based on the movement of the second sensing element, the second sensor output signal corresponding to the second directionality pick-up pattern exhibited by the second sensing element, and iii) a third sensor output signal based on a combination of the first electrical signal generated based on the movement of the first sensing element and the second electrical signal generated based on the movement of the second sensing element, the third sensor output signal corresponding to a third directionality pick-up pattern that is different from the first directionality pick-up pattern exhibited by the first sensing element and the second directionality pick-up pattern of exhibited by the second sensing element.

15. The acoustic sensor device of claim 14, wherein:
the first directionality pick-up pattern comprises a dipole directional pattern,
the second directionality pick-up pattern comprises an omnidirectional pattern, and
the third directionality pick-up pattern comprises one of a cardioid pattern, a super-cardioid pattern, and a hyper-cardioid pattern.

16. The acoustic sensor device of claim 13, wherein the ASIC is configured to generate a sound intensity output based on a multiplication the first electrical signal generated based on the movement of the first sensing element with the second electrical signal generated based on the movement of the second sensing element.

17. An acoustic sensor device, comprising:
a package;
a substrate disposed in the package or forming a part of the package;
one or more microelectromechanical system (MEMS) transducers supported by the substrate and packaged in the package, the one or more MEMS transducers including a plurality of sensing elements including at least a first sensing element and a second sensing element;
a first sound port formed in the package and configured to expose a first side of the first sensing element and a first side of the second sensing element to an ambient environment; and
a second sound port formed in the package and configured to couple a second side of the first sensing element to the ambient environment such that the first sensing element exhibits a directional pick-up pattern with respect to sound waves traveling in the ambient environment;
wherein a second side of the second sensing element is not exposed to the ambient environment such that the second sensing element exhibits an omnidirectional pick-up pattern with respect to the sound waves traveling in the ambient environment.

18. The acoustic sensor device of claim 17, further comprising a first air volume, a second air volume and a third air volume, wherein:
the first side of the first sensing element and the first side of the second sensing element are both exposed to the first air volume such that the first sound port exposes the first side to the first sensing element and the first side of the second sensing element to the ambient environment via the first air volume,
the second side of the first sensing element is exposed to the second air volume such that the second sound port exposes the second side of the first sensing element to the ambient environment via the second air volume, and
the second side of the second sensing element is exposed to the third air volume, wherein the third air volume is sealed from the ambient environment.

19. The acoustic sensor device of claim 18, further comprising at least one IC device coupled to the one or more MEMS transducers, the at least one IC device configured to selectively generate one or more of i) a directional sensor output signal generated based on movement of the first sensing element ii) an omnidirectional sensor output signal generated based on movement of the second sensing element, and ii) a combined sensor output signal generated based on a combination of the directional sensor output signal and the omnidirectional sensor output signal.

20. The acoustic sensor device of claim 17, wherein:
the first sensing element is formed on a first semiconductor die,
the second sensing element is formed on a second semiconductor dies separate from the first semiconductor die.

21. The acoustic sensor device of claim 17, wherein the first sensing element and the second sensing element are formed a semiconductor die, wherein the semiconductor die comprises the first sensing element positioned over a first cavity formed in the semiconductor die and the second sensing element positioned over a second cavity formed in the semiconductor die, the second cavity being separate from the first cavity in the semiconductor die.
